(19) United States
(12) Patent Application Publication
(10) Pub. No.: US 2023/0165117 A1
(43) Pub. Date: May 25, 2023

(54) DISPLAY PANEL, MASK PLATE, AND MANUFACTURING METHOD OF DISPLAY PANEL

(71) Applicant: Wuhan China Star Optoelectronics Semiconductor Display Technology Co., Ltd., Wuhan, Hubei (CN)

(72) Inventor: Xiao DU, Wuhan, Hubei (CN)

(73) Assignee: Wuhan China Star Optoelectronics Semiconductor Display Technology Co., Ltd., Wuhan, Hubei (CN)

(21) Appl. No.: 17/051,488

(22) PCT Filed: Jun. 30, 2020
(86) PCT No.: PCT/CN2020/099267

§ 371 Date: Oct. 29, 2020

(30) Foreign Application Priority Data
Apr. 26, 2020 (CN) 202010339907.6

(51) Int. Cl. H10K 59/80; H10K 71/60; C23C 14/04

(52) U.S. Cl. CPC H10K 59/876; H10K 59/873; H10K 59/80524; H10K 71/60; C23C 14/042

(57) ABSTRACT

A display panel, a mask plate, and a manufacturing method of the display panel are provided. The display area includes an installation area and a non-installation area. The installation area is configured to install a preset component. The display panel further includes a pixel layer. The pixel layer includes a plurality of first sub-pixels disposed in the non-installation area and a plurality of second sub-pixels disposed in the installation area. Each of the plurality of first sub-pixels includes a first cathode, and each of the plurality of second sub-pixels includes a second cathode, wherein a thickness of the second cathode is less than a thickness of the first cathode.

### BACKGROUND

### Field of Invention

The present disclosure relates to a field of display technology, and more particularly, to a display panel, a mask plate, and a manufacturing method of the display panel.

### Description of the Prior Art

Along with development of display technologies, display devices including full screens are becoming more and more popular.

In a display panel, a cathode layer is made of translucent material which will block light. If an under-screen camera technology is adopted to achieve a full screen, an overly thick cathode layer disposed in an installation area of a camera will cause light transmittance to be excessively low.

Therefore, it is necessary to provide a display panel which can increase the light transmittance of the installation area of the camera.

### SUMMARY

A purpose of the present disclosure is to provide a display panel, a mask plate, and a manufacturing method of a display panel, improving a light transmittance of an installation area of the display panel.

The present disclosure provides a display panel, including:
a display area, including:
   an installation area, configured to install a preset component, and
   a non-installation area defined by an area of the display area excluding the installation area, the display panel further including:
a pixel layer, including:
   a plurality of first sub-pixels, disposed in the non-installation area, each of the plurality of first sub-pixels including a first cathode;
   a plurality of second sub-pixels, disposed in the installation area, each of the plurality of second sub-pixels including a second cathode, wherein a thickness of the second cathode is less than a thickness of the first cathode.

According to an embodiment, the thickness of the first cathode ranges from 70 angstroms to 250 angstroms, and the thickness of the second cathode ranges from 50 angstroms to 120 angstroms.

According to an embodiment, the display panel further includes:
a first encapsulation layer disposed on the pixel layer;
a first compensation layer disposed on the first encapsulation layer, wherein the first compensation layer is disposed opposite to an opening area of second sub-pixel.

According to an embodiment, the display panel further includes:
a touch electrode layer disposed in a same layer as the first compensation layer.

According to embodiment, constituent materials of the first compensation layer include translucent metal or alloy.

According to an embodiment, a thickness of the first compensation layer ranges from 20 angstroms to 130 angstroms.

According to an embodiment, a sum of a thickness of the first compensation layer and the thickness of the second cathode ranges from 70 angstroms to 250 angstroms.

According to an embodiment, the display panel further includes:
a second encapsulation layer disposed on the pixel layer; and
a polarizer, including:
   a second compensation layer, wherein the second compensation layer is disposed opposite to the opening area of the second sub-pixel when the polarizer is disposed on the second encapsulation layer.

According to an embodiment, constituent materials of the second compensation layer includes translucent metal or alloy.

According to an embodiment, a thickness of the second compensation layer ranges from 20 angstroms to 130 angstroms.

According to an embodiment, a sum of a thickness of the second compensation layer and the thickness of the second cathode ranges from 70 angstroms to 250 angstroms.

According to an embodiment, the installation area has a shape of a rectangle, a rounded rectangle, or a semicircle.

The present disclosure further provides a mask plate, configured to carry out vapor deposition on cathodes of a plurality of display panels, each of the plurality of display panels including a display area, the display area including an installation area configured to install a preset component, and a non-installation area defined by an area of the display area excluding the installation area, wherein the mask plate includes:
a first mask plate, including:
   a first metal frame, including at least one first opening area, each of the at least one first opening area configured to correspond to a corresponding display area;
   a second mask plate, including:
      a second metal frame including at least one second opening area, each of the at least one second opening area configured to correspond to a corresponding non-installation area; and
      at least one shielding portion, each of the at least one shielding portion connected to the second metal frame, and each of the at least one shielding portion configured to correspond to a corresponding installation area.

According to an embodiment, a shape of each of the at least one first opening area is the same as a shape of the corresponding display area, and a size of each of the at least one first opening area is larger than a size of the corresponding display area.

According to an embodiment, a border of each of the at least one first opening area and a border of each of the at least one second opening area both correspond to a pixel defining portion of a corresponding display panel.

According to an embodiment, each of the at least one shielding portion includes a shielding body and a connector disposed on both sides of the shielding body, and each of the at least one shielding portion connects to the second metal frame through the connector.

The present disclosure further provides a manufacturing method of a display panel, the display panel including a display area, the display area including an installation area configured to install a preset component, and a non-installation area defined by an area of the display area excluding the installation area, wherein the manufacturing method includes following steps:
providing the display panel, a first mask plate, and a second mask plate, wherein the first mask plate includes a first opening area, and the second mask plate includes a second opening area and a shielding portion;
making the first opening area of the first mask plate correspond to the display area, performing a first cathode vapor deposition in the display area, forming an initial cathode of a first sub-pixel in the non-installation area, and forming a second cathode of a second sub-pixel in the installation area; and
making the second opening area of the second mask plate correspond to the non-installation area, and making the shielding portion of the second mask plate correspond to the installation area, and performing a second cathode vapor deposition on the initial cathode disposed in the display area to form a first cathode of a first sub-pixel.

According to an embodiment, after the step of making the second opening area of the second mask plate correspond to the non-installation area, making the shielding portion of the second mask plate correspond to the installation area, and performing the second cathode vapor deposition on the initial cathode disposed in the display area to form a first cathode of the first sub-pixel, further including:
forming a first encapsulation layer on the first sub-pixel and the second sub-pixel; and
forming a first compensation layer on the first encapsulation layer, and making the first compensation layer correspond to an opening area of the second sub-pixel.

According to an embodiment, after the step of making the second opening area of the second mask plate correspond to the non-installation area, making the shielding portion of the second mask plate correspond to the installation area, and performing the second cathode vapor deposition on the initial cathode disposed in the display area to form the first cathode of a first sub-pixel, further including:
forming a second encapsulation layer on the first sub-pixel and the second sub-pixel; and
attaching a polarizer on the second encapsulation layer, and making a second compensation layer of the polarizer correspond to an opening area of the second sub-pixel.

The display screen and the display device according to an embodiment of the present disclosure increase the light transmittance of the installation area of the display panel by increasing a light-emitting area of pixels away from a non-bending area.

### BRIEF DESCRIPTION OF DRAWINGS

Technical solutions and other beneficial effects of the present disclosure will be obvious by describing the specific implementation of the present disclosure in detail with reference to the accompanying drawings.

FIG. 1 is a first structural schematic diagram of a display panel according to an embodiment of the present disclosure.

FIG. 2 is a second structural schematic diagram of the display panel according to an embodiment of the present disclosure.

FIG. 3 is a third structural schematic diagram of the display panel according to an embodiment of the present disclosure.

FIG. 4 is a first structural schematic diagram of a mask plate according to an embodiment of the present disclosure.

FIG. 5 is a second structural schematic diagram of the mask plate according to an embodiment of the present disclosure.

FIG. 6 is a third structural schematic diagram of the mask plate according to an embodiment of the present disclosure.

FIG. 7 is a fourth structural schematic diagram of the mask plate according to an embodiment of the present disclosure.

FIG. 8 is a flow schematic diagram of a manufacturing method of a display panel according to an embodiment of the present disclosure.

FIG. 9 is a first scene schematic diagram of the manufacturing method of the display panel according to an embodiment of the present disclosure.

FIG. 10 is a second scene schematic diagram of the manufacturing method of the display panel according to an embodiment of the present disclosure.

### DETAILED DESCRIPTION OF PREFERRED EMBODIMENTS

Embodiments of the present disclosure are described in detail with the technical matters, structural features, achieved objects, and effects with reference to the accompanying drawings as follows. It is clear that the described embodiments are part of embodiments of the present disclosure, but not all embodiments. Based on the embodiments of the present disclosure, all other embodiments to those of ordinary skill in the premise of no creative efforts obtained, should be considered within the scope of protection of the present disclosure.

In the description of the present disclosure, it should be understood that orientations or position relationships indicated by the terms “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, “clockwise”, and “counter-clockwise” are based on orientations or position relationships illustrated in the drawings. The terms are used to facilitate and simplify the description of the present disclosure, rather than indicate or imply that the devices or elements referred to herein are required to have specific orientations or be constructed or operate in the specific orientations. Accordingly, the terms should not be construed as limiting the present disclosure. In addition, the term “first”, “second” are for illustrative purposes only and are not to be construed as indicating or imposing a relative importance or implicitly indicating the number of technical features indicated. Thus, a feature that limited by “first”, “second” may expressly or implicitly include at least one of the features. In the description of the present disclosure, the meaning of “plural” is two or more, unless otherwise specifically defined.

In the description of the present disclosure, it should be noted that unless otherwise clearly defined and limited, the terms “mounted”, “connected/coupled”, and “connection” should be interpreted broadly. For example, the terms may refer to a fixed connection, a detachable connection, or an integral connection; the terms may also refer to a mechanical connection, an electrical connection, or communication with each other; the terms may further refer to a direct connection, an indirect connection through an intermediary, or an interconnection between two elements or interactive relationship between two elements. Those skilled in the art can understand the specific meanings of the above-mentioned terms in the present disclosure according to circumstances.

In the present disclosure, it should he noted that unless otherwise clearly defined and limited, a first feature “on” or “under” a second feature may mean that the first feature directly contacts the second feature, or that the first feature contacts the second feature via an additional feature there between instead of directly contacting the second feature. Moreover, the first feature “on”, “above”, and “over” the second feature may mean that the first feature is right over or obliquely upward over the second feature or mean that the first feature has a horizontal height higher than that of the second feature. The first feature “under”, “below”, and “beneath” the second feature may mean that the first feature is right beneath or obliquely downward beneath the second feature or mean that that horizontal height of the first feature is lower than that of the second feature.

The following description provides various embodiments or examples for implementing various structures of the present disclosure. To simplify the description of the present disclosure, parts and settings of specific examples are described as follows. Certainly; they are only illustrative, and are not intended to limit the present disclosure. Further, reference numerals and reference letters may be repeated in different examples. This repetition is for purposes of simplicity and clarity and does not indicate a relationship of the various embodiments and/or the settings. Furthermore, the present disclosure provides specific examples of various processes and materials, however, applications of other processes and/or other materials may be appreciated those skilled in the art.

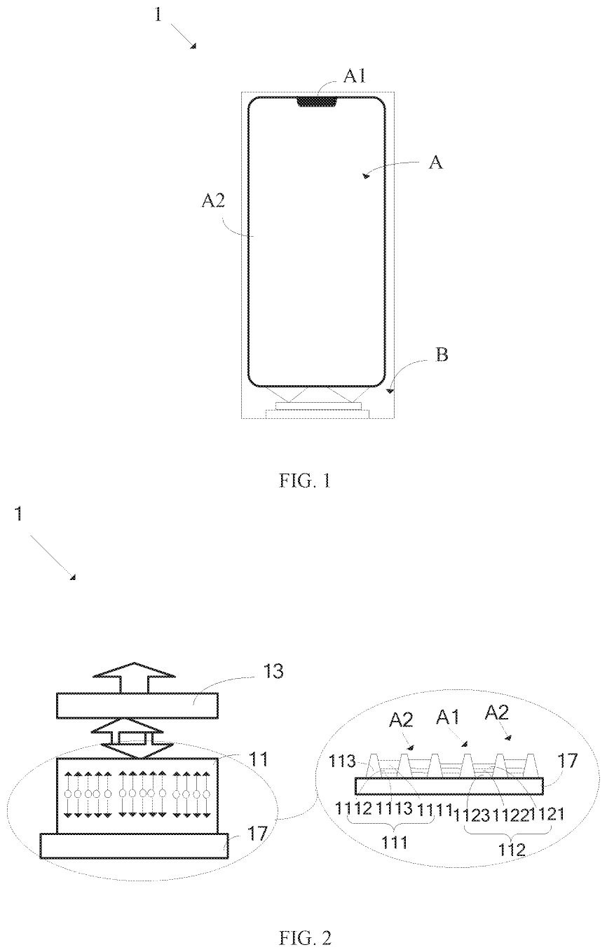

The present disclosure provides a display panel. Please refer to FIG. 1, FIG. 1 is a structural schematic diagram of a display panel according to an embodiment of the present disclosure.

As shown in FIG. 1, the display panel 1 includes a display area A and a non-display area B. The non-display area B is disposed around the display area A. Wherein, the display area A is configured to display. The non-display area B is configured to bond driver chips, flexible circuit boards, etc.

Wherein, the display area A includes an installation area A1 and a non-installation area A2. The non-installation area A2 is an area of the display area A excluding the installation area A1. Wherein, the installation area A1 is configured to install a preset component. Wherein, the preset component can be a camera, a distance sensor, a light sensor, and other components. The preset component mentioned above has a high light requirement during operation, and requires a high light transmittance of the installation area A1.

Wherein, the installation area A1 has a shape of a rectangle, a rounded rectangle, a semicircle, or the like. The installation area A1 having a rectangular shape can be disposed on a top or a corner of the display area A.

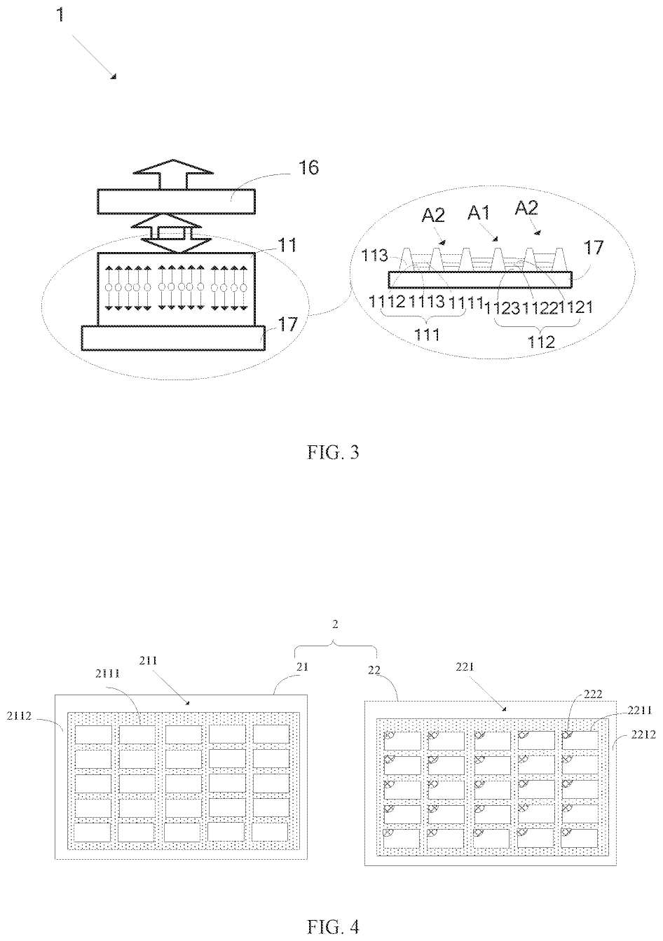

As shown in FIG. 2 or FIG. 3, the display panel 1 further includes a substrate 17 and a pixel layer 11. Wherein, the substrate 17 is configured to carry components disposed thereon. The pixel layer 11 includes a plurality of first sub-pixels 111 and a plurality of second sub-pixels 112. Wherein, the plurality of first sub-pixels 111 are disposed in the non-installation area A2, and the plurality of second sub-pixels 112 are disposed in the installation area A1. It should be noted that the display panel 1 further includes a plurality of pixel defining potions 113. Adjacent sub-pixels are separated by disposing a pixel defining portion 113.

As shown in FIG. 2 or FIG. 3, each first sub-pixel 111 includes a first cathode 1111, a first light-emitting layer 1112, and a first anode 1113. Each second sub-pixel 112 includes a second cathode 1121, a second light-emitting layer 1122, and a second anode 1123. Wherein, a thickness of the second cathode 1121 is less than a thickness of the first cathode 1111. By reducing the thickness of the second cathode 1121, light shielding of the second cathode 1121 of the installation area A1 can be reduced, and a light transmittance of the installation area A1 can be improved.

According to an embodiment, the thickness of the first cathode 1111 ranges from 70 angstroms to 250 angstroms, and the thickness of the second cathode 1121 ranges from 50 angstroms to 120 angstroms.

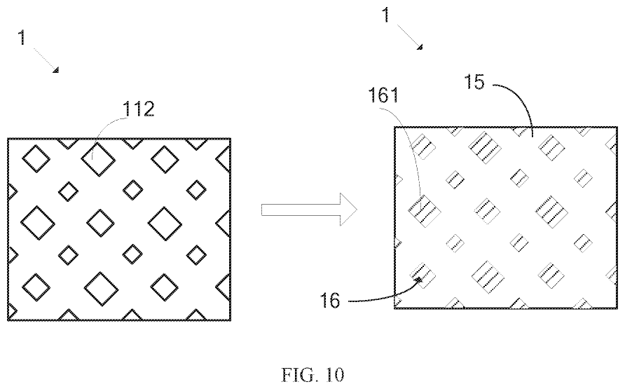

As shown in FIG. 9, the display panel 1 further includes a first encapsulation layer 12 and a first compensation layer 13. The first encapsulation layer 12 is disposed on the pixel layer 11. The first compensation layer 13 is disposed on the first encapsulation layer 12. The first compensation layer 13 is disposed opposite to an opening area of second sub-pixel 112. The first compensation layer 13 is configured as a microcavity compensation layer and forms a microcavity effect with the second cathode 1121 to enhance a light-emitting efficiency of the second light-emitting layer 1122.

The first compensation layer 13 can be made of translucent metal or alloy such as magnesium, silver, and magnesium-silver alloy. Preferably, the first compensation layer 13 is made of a translucent alloy, which can improve a film-forming performance of the first compensation layer 13. A thickness of the first compensation layer 13 ranges from 20 angstroms to 130 angstroms. Wherein, a sum of the thickness of the first compensation layer 13 and the thickness of the second cathode 1121 ranges from 70 angstroms to 250 angstroms.

In an embodiment, as shown in FIG. 9, the display panel 1 further includes a touch electrode layer 14. The touch electrode layer 14 is disposed with the first compensation layer 13 in a same layer. Specifically, the first compensation layer 13 can be formed first, and then the touch electrode layer 14 can be formed. In an embodiment, the first compensation layer 13 and the touch electrode 14 can also be formed by one etching process.

In an embodiment, as shown in FIG. 3 and FIG. 10, the display panel 1 further includes a second encapsulation layer 15 and a polarizer 16. The second encapsulation layer 15 is disposed on the pixel layer 11. The polarizer 16 includes a second compensation layer 161. The second compensation layer 161 is disposed opposite to the opening area of the second sub-pixel 112 when the polarizer 16 is disposed on the second encapsulation layer 15. The second compensation layer 161 is configured as a microcavity compensation layer and forms a microcavity effect with the second cathode 1121 to enhance a light-emitting efficiency of the second light-emitting layer 1122.

The second compensation layer 161 can be made of translucent metal or alloy such as magnesium, silver, and magnesium-silver alloy. Preferably, the second compensation layer 161 is made of a translucent alloy, which can improve a film-forming performance of the second compensation layer 161. A thickness of the second compensation layer 161 ranges from 20 angstroms to 130 angstroms. Wherein, a sum of the thickness of the second compensation layer 161 and the thickness of the second cathode 1121 ranges from 70 angstroms to 250 angstroms.

The display panel, according to an embodiment of the present disclosure, increases the light transmittance of the installation area of the display panel by reducing a thickness of a cathode of the installation area.

The present disclosure further provides a mask plate configured to carry out vapor deposition on cathodes of a plurality of display panels. As shown in FIG. 1, the display panel includes a display area A. The display area A includes an installation area A1 and a non-installation area A2. The installation area A1 is configured to install a preset component. The non-installation area A2 is an area of the display area A excluding the installation area A1. Wherein, the preset component can be a camera, a distance sensor, a light sensor, and other components. The preset component mentioned above has a high light requirement during operation, and requires a high light transmittance of the installation area A1. Wherein, the installation area A1 has a shape of a rectangle, a rounded rectangle, a semicircle, or the like. The installation area A1 having a rectangular shape can be disposed on a top or a corner of the display area A.

Please refer to FIG. 4, FIG. 4 is a structural schematic diagram of a mask plate according to an embodiment of the present disclosure. The mask plate 2 includes a first mask plate 21 and a second mask plate 22.

As shown in FIG. 4, the first mask plate includes a first metal frame 211. The first metal frame 211 includes at least one first opening area 2111. The first mask plate 21 can carry out vapor deposition on cathodes of a plurality of display panels 1. Wherein, each first opening area 2111 is configured to correspond to a display area A of a display panel 1. A shape of the first opening area 2111 is the same as a shape of the display area A, and a size of the first opening area 2111 is larger than a size of the display area A. Specifically, the first opening area 2111 expands outward from the display area A by 5 micron to 500 micron.

In an embodiment, the first metal frame 211 further includes a first frame body 2112. The at least one first opening area 2111 is fixed on the first frame body 2112 by laser welding.

A thickness of the first mask plate 21 ranges from 0.02 mm to 0.2 mm. It should be noted that a border of the first opening area 2111 corresponds to the pixel defining portion 113 of the display panel 1. A border shape of the first opening area 2111 is disposed according to an arrangement of the sub-pixels in the pixel layer 11. Further, the border shape of the first opening area 2111 can be a smooth straight edge or a curve, which is specifically disposed according to a shape of the pixel defining portion 113.

As shown in FIG. 4, the second mask plate 22 includes a second metal frame 221 and at least one shielding portion 222. The second metal frame 221 includes at least one second opening area 2211. Wherein, the shielding portion 222 is connected to the second metal frame 221. The second mask plate 22 can carry out vapor deposition on the cathodes of a plurality of display panels 1. Wherein, the second opening area 2211 is configured to correspond to the non-installation area A2 of a single display panel 1. The shielding portion 222 is connected to a corresponding second opening area 2211. The shielding portion 222 is configured to correspond to the installation area A1.

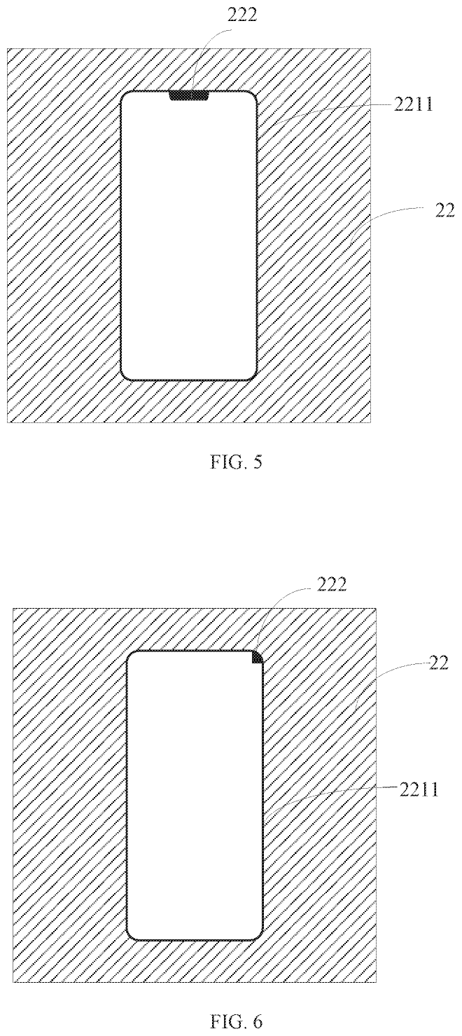

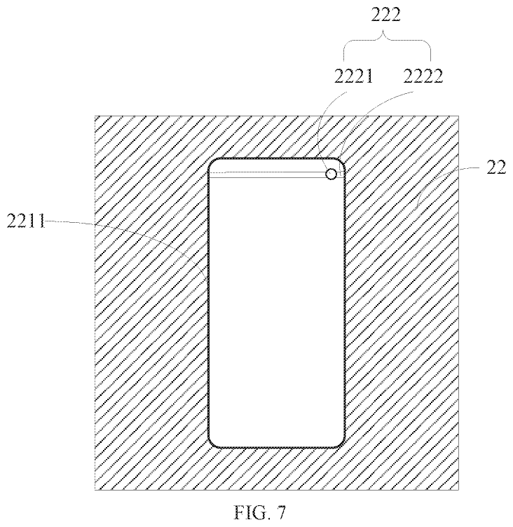

As shown in FIG. 5 or FIG. 6, the shielding portion 222 can be an irregular shape or rectangular, and can be disposed at a top or a corner of the second opening area 2211. At this time, the installation area A1 of the display panel 1 can be disposed on an edge area of the display panel 1. As shown in FIG. 7, the shielding portion 222 includes a shielding body 2221 and a connector 2222 disposed on both sides of the shielding body 2221. The shielding portion 222 is connected to the second metal frame 221 by the connector 2222. At this time, the installation area A1 can be disposed in any area of the display panel 1. Wherein, the shielding portion 222 can be fixed on the second opening area 2211 by laser welding, or can be integrally formed with the second opening area 2211.

In an embodiment, as shown in FIG. 4, the second metal frame 221 further includes a second frame body 2212. The at least one second opening area 2211 is fixed on the second frame body 2212 by laser welding. A thickness of the second mask plate 22 ranges from 0.02 mm to 0.2 mm.

When manufacturing the display panel 1 by the mask plate according to the embodiment of the present disclosure, the first opening area 2111 of the first mask plate 21 is first made to correspond to the display area A of the display panel 1 to carry out a first cathode vapor deposition on the display panel 1. An initial cathode of the first sub-pixel 111 is formed in the non-installation area A2, and the second cathode 1121 of the second sub-pixel 112 is formed in the installation area A1. At this time, a thickness of the initial cathode and a thickness of the second cathode 1121 range from 50 angstroms to 120 angstroms.

Then, the first mask plate 21 is replaced by the second mask plate 22 to continue to carry out cathode vapor deposition on the display panel 1. The second opening area 2211 of the second mask plate 22 is made to correspond to the non-installation area A2, and the shielding portion 222 of the second mask plate 22 is made to correspond to the installation area A1 to finish a second cathode vapor deposition. At this time, the second cathode vapor deposition is carried out on the initial cathode disposed in the non-installation area A2 to form the first cathode 1111 of the first sub-pixel 111. A thickness of the second cathode vapor deposition ranges from 20 angstroms to 130 angstroms. The thickness of the first cathode 1111 finally obtained by vapor deposition ranges from 70 angstroms to 250 angstroms.

By adopting the mask plate 2 to carry out vapor deposition on cathodes according to the embodiment of the present disclosure, not only can the thickness of the second cathode 1121 of the installation area A1 be reduced, but also laser burning to reduce the thickness of the second cathode 1121 is unnecessary, thereby reducing damage to the display panel during a burning process, and improving a yield rate of the display panel.

The mask plate according to the embodiment of the present disclosure can reduce the thickness of the cathode of the installation area and improve the light transmittance of the installation area of the display panel, when manufacturing the display panel.

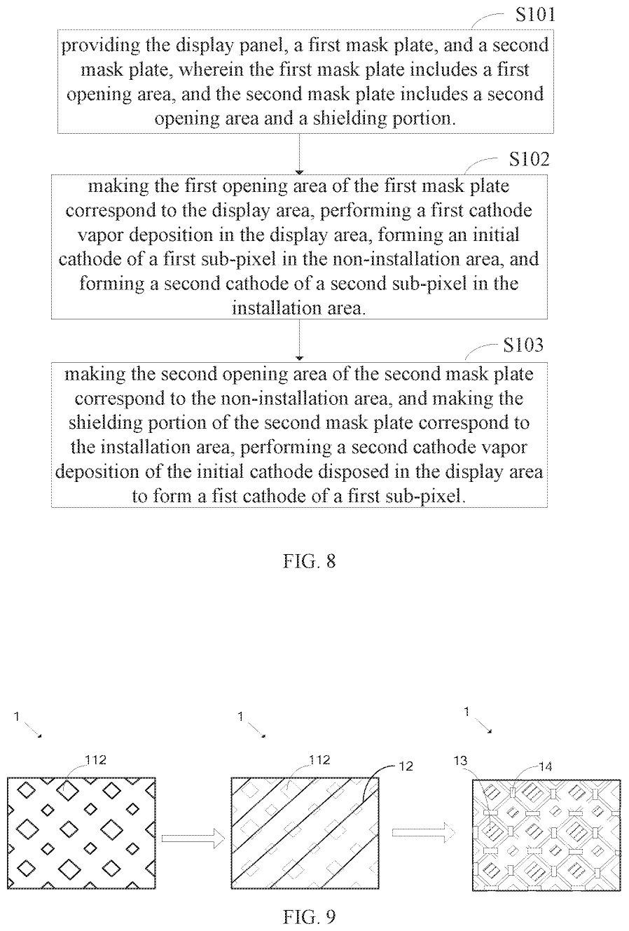

The present disclosure further provides a manufacturing method of a display panel. Please refer to FIG. 8, FIG. 8 is a flow schematic diagram of the manufacturing method of the display panel according to an embodiment of the present disclosure.

Step S101, providing the display panel, a first mask plate, and a second mask plate, wherein the first mask plate includes a first opening area, and the second mask plate includes a second opening area and a shielding portion.

As shown in FIG. 1, the display panel 1 includes a display area A and a non-display area B. The non-display area B is disposed around the display area A. Wherein, the display area A is configured to display. The non-display area B is configured to bond driver chips, flexible circuit boards, etc.

Wherein, the display area A includes an installation area A1 and a non-installation area A2. The non-installation area A2 is an area of the display area A excluding the installation area A1. Wherein, the installation area A1 is configured to install a preset component. Wherein, the preset component can be a camera, a distance sensor, a light sensor, and other components. The preset component mentioned above has a high light requirement during operation, and requires a high light transmittance of the installation area A1.

Wherein, the installation area A1 has a shape of a rectangle, a rounded rectangle, a semicircle, or the like. The installation area A1 having a rectangular shape can be disposed on a top or a corner of the display area A.

As shown in FIG. 4, the first mask plate 21 includes a first metal frame 211. The first metal frame 211 includes at least one first opening area 2111. The first mask plate 21 can carry out vapor deposition on cathodes of a plurality of display panels 1. Wherein, each first opening area 2111 is configured to correspond to a display area A of a display panel 1. A shape of the first opening area 2111 is the same as a shape of the display area A, and a size of the first opening area 2111 is larger than a size of the display area A. Specifically, the first opening area 2111 expands outward from the display area A by 5 micron to 500 micron.

In an embodiment, the first metal frame 211 further includes a first frame body 2112. The at least one first opening area 2111 is fixed on the first frame body 2112 by laser welding.

A thickness of the first mask plate 21 ranges from 0.02 mm to 0.2 mm. It should be noted that a border of the first opening area 2111 corresponds to a pixel defining portion 113 of the display panel 1. A border shape of the first opening area 2111 is disposed according to an arrangement of sub-pixels in a pixel layer 11. Further, the border shape of the first opening area 2111 can be a smooth straight edge or a curve, which is specifically disposed according to a shape of the pixel defining portion 113.

As shown in FIG. 4, the second mask plate 22 includes a second metal frame 221 and at least one shielding portion 222. The second metal frame 221 includes at least one second opening area 2211. Wherein, the shielding portion 222 is connected to the second metal frame 221. The second mask plate 22 can carry out vapor deposition on the cathodes of a plurality of display panels 1. Wherein, the second opening area 2211 is configured to correspond to the non-installation area A2 of a single display panel 1. The shielding portion 222 is connected to a corresponding second opening area 2211. The shielding portion 222 is configured to correspond to the installation area A1.

As shown in FIG. 5 or FIG. 6, the shielding portion 222 can be an irregular shape or rectangular, and can be disposed at a top or a corner of the second opening area 2211. At this time, the installation area A1 of the display panel 1 can be disposed on an edge area of the display panel 1. As shown in FIG. 7, the shielding portion 222 includes a shielding body 2221 and a connector 2222 disposed on both sides of the shielding body 2221. The shielding portion 222 is connected to the second metal frame 221 by the connector 2222. At this time, the installation area A1 can be disposed in any area of the display panel 1. Wherein, the shielding portion 222 can be fixed on the second opening area 2211 by laser welding, or can be integrally formed with the second opening area 2211.

In an embodiment, the second metal frame 221 further includes a second frame body 2212. The at least one second opening area 2211 is fixed on the second frame body 2212 by laser welding. A thickness of the second mask plate 22 ranges from 0.02 mm to 0.2 mm.

Step S102, making the first opening area of the first mask plate correspond to the display area, performing a first cathode vapor deposition in the display area, forming an initial cathode of a first sub-pixel in the non-installation area, and forming a second cathode of a second sub-pixel in the installation area.

Specifically, the first mask plate 21 is transferred into a vapor deposition machine, and the display panel 1 is transferred into a cathode vapor deposition chamber. An alignment deviation between the first mask plate 21 and the display panel 1 is adjusted to make the first opening area 2111 of the first mask plate 21 correspond to the display area A of the display panel 1. The first mask plate 21 is firmly attached to the display panel 1 to complete the first vapor deposition. At this time, an initial cathode of the first sub-pixel 111 is formed in the non-installation area A2, and the second cathode 1121 of the second sub-pixel 112 is formed in the installation area A1. At this time, a thickness of the initial cathode and a thickness of the second cathode 1121 range from 50 angstroms to 120 angstroms.

Step S103, making the second opening area of the second mask plate correspond to the non-installation area, making the shielding portion of the second mask plate correspond to the installation area, and performing a second cathode vapor deposition on the initial cathode disposed in the display area to form a first cathode of a first sub-pixel.

In an embodiment, the second vapor deposition can be continued in the cathode vapor deposition chamber. The first mask plate 21 is replaced by the second mask plate 22 to continue carrying out the cathode vapor deposition on the display panel 1. In another embodiment, the display panel 1 and the second mask plate 22 can be transferred into another cathode vapor deposition chamber to carry out the cathode vapor deposition.

Similarly, an alignment deviation between the second mask plate 22 and the display panel 1 is adjusted to make the second opening area 2211 of the second mask plate 22 correspond to the non-installation area A2 of the display panel 1, and make the shielding portion 222 of the second mask plate 22 correspond to the installation area A1. The second mask plate 22 is firmly attached to the display panel 1 to complete the second vapor deposition. At this time, the second cathode vapor deposition is carried out on the initial cathode disposed in the non-installation area A2 to form the first cathode of the first sub-pixel. A thickness of the second cathode vapor deposition ranges from 20 angstroms to 130 angstroms. The thickness of the first cathode 1111 finally obtained by vapor deposition ranges from 70 angstroms to 250 angstroms.

The microcavity effect formed between the second cathode and the anode of the display panel is reduced when the thickness of the second cathode of the installation area is reduced. Therefore, compensation layers are further provided in the embodiment of the disclosure to compensate for the microcavity effect.

In an embodiment, after obtaining the first cathode and the second cathode by the vapor deposition, it is also possible to:

(A1) form a second encapsulation layer on the first sub-pixel and the second sub-pixel.

(A2) form a first compensation layer on the second encapsulation layer, and make the first compensation layer correspond to an opening area of the second sub-pixel.

Wherein, the first encapsulation layer is configured to encapsulate the display panel to prevent the display panel from being corroded by water and oxygen. The first compensation layer 13 is configured as a microcavity compensation layer and forms a microcavity effect with the second cathode 1121 to enhance a light-emitting efficiency of the second light-emitting layer 1122.

The first compensation layer 13 can be made of translucent metal or alloy such as magnesium, silver, and magnesium-silver alloy. Preferably, the first compensation layer 13 is made of a translucent alloy, which can improve a film-forming performance of the first compensation layer 13. A thickness of the first compensation layer 13 ranges from 20 angstroms to 130 angstroms. Wherein, a sum of the thickness of the first compensation layer 13 and the thickness of the second cathode 1121 ranges from 70 angstroms to 250 angstroms.

As shown in FIG. 9, the first compensation layer 13 can be formed first, and then a touch electrode layer 14 can be formed. In an embodiment, the first compensation layer 13 and the touch electrode 14 can also be formed by one etching process.

In an embodiment, after obtaining the first cathode and the second cathode by the vapor deposition, it is also possible to:

Form a first encapsulation layer on the first sub-pixel and the second sub-pixel.

Attach a polarizer on the first encapsulation layer, and making a second compensation layer of the polarizer correspond to an opening area of the second sub-pixel.

Wherein, the second encapsulation layer is configured to encapsulate the display panel to prevent the display panel from being corroded by water and oxygen.

The polarizer 16 includes the second compensation layer 161. The second compensation layer 161 is disposed opposite to the opening area of the second sub-pixel 112 when the polarizer 16 is disposed on the second encapsulation layer 15. The second compensation layer 161 is configured as a microcavity compensation layer and forms a microcavity effect with the second cathode 1121 to enhance a light-emitting efficiency of the second light-emitting layer 1122.

The second compensation layer 161 can be made of translucent metal or alloy such as magnesium, silver, and magnesium-silver alloy. Preferably, the second compensation layer 161 is made of a translucent alloy, which can improve a film-forming performance of the second compensation layer 161. A thickness of the second compensation layer 161 ranges from 20 angstroms to 130 angstroms. Wherein, a sum of the thickness of the second compensation layer 161 and the thickness of the second cathode 1121 ranges from 70 angstroms to 250 angstroms.

The manufacturing method of the display panel according to an embodiment of the present disclosure increases the light transmittance of the installation area of the display panel by reducing a thickness of a cathode of the installation area.

In the foregoing embodiments, the description of each embodiment has its own emphasis. For the parts that are not described in detail in one embodiment, reference may be made to related descriptions in other embodiments.

The display panel, the mask plate, and the manufacturing method of the display panel provided by the embodiments of the present disclosure are described in detail. The principles and implementations of the present disclosure are described in combination with specific embodiments. The above description of the embodiments is merely for the purpose of understanding the disclosure. In the meantime, for those skilled in the art, there will be changes in the specific implementation and application scope according to the idea of the present disclosure. In conclusion, the content of the specification of the present disclosure should not be construed as limitations of the scope of the present disclosure.

What is claimed is:

1. A display panel, comprising:
a display area, comprising:
an installation area configured to install a preset component, and
a non-installation area defined by an area of the display area excluding the installation area, the display panel further comprising:
a pixel layer, comprising:
a plurality of first sub-pixels disposed in the non-installation area, each of the plurality of first sub-pixels comprising a first cathode; and
a plurality of second sub-pixels disposed in the installation area, each of the plurality of second sub-pixels comprising a second cathode, wherein a thickness of the second cathode is less than a thickness of the first cathode.

2. The display panel as claimed in claim 1, wherein the thickness of the first cathode ranges from 70 angstroms to 250 angstroms, and the thickness of the second cathode ranges from 50 angstroms to 120 angstroms.

3. The display panel as claimed in claim 1, wherein the display panel further comprises:
a first encapsulation layer disposed on the pixel layer;
a first compensation layer disposed on the first encapsulation layer, wherein the first compensation layer is disposed opposite to an opening area of second sub-pixel.

4. The display panel as claimed in claim 3, wherein the display panel further comprises:
a touch electrode layer disposed in a same layer as the first compensation layer.

5. The display panel as claimed in claim 3, wherein constituent materials of the first compensation layer comprise translucent metal or alloy.

6. The display panel as claimed in claim 3, wherein a thickness of the first compensation layer ranges from 20 angstroms to 130 angstroms.

7. The display panel as claimed in claim 3, wherein a sum of a thickness of the first compensation layer and the thickness of the second cathode ranges from 70 angstroms to 250 angstroms.

8. The display panel as claimed in claim 1, wherein the display panel further comprises:
a second encapsulation layer disposed on the pixel layer; and
a polarizer, comprising:
a second compensation layer, wherein the second compensation layer is disposed opposite to the opening area of the second sub-pixel when the polarizer is disposed on the second encapsulation layer.

9. The display panel as claimed in claim 8, wherein constituent materials of the second compensation layer comprises translucent metal or alloy.

10. The display panel as claimed in claim 8, wherein a thickness of the second compensation layer ranges from 20 angstroms to 130 angstroms.

11. The display panel as claimed in claim 8, wherein a sum of a thickness of the second compensation layer and the thickness of the second cathode ranges from 70 angstroms to 250 angstroms.

12. The display panel as claimed in claim 1, wherein the installation area has a shape of a rectangle, a rounded rectangle, or a semicircle.

13. A mask plate, configured to carry out vapor deposition on cathodes of a plurality of display panels, each of the plurality of display panels comprising a display area, the display area comprising an installation area configured to install a preset component and a non-installation area defined by an area of the display area excluding the installation area, wherein the mask plate comprises:
a first mask plate, comprising:
a first metal frame comprising at least one first opening area, each of the at least one first opening area configured to correspond to a corresponding display area;
a second mask plate, comprising:
a second metal frame comprising at least one second opening area, each of the at least one second opening area configured to correspond to a corresponding non-installation area; and
at least one shielding portion, each of the at least one shielding portion connected to the second metal frame, and each of the at least one shielding portion configured to correspond to a corresponding installation area.

14. The mask plate as claimed in claim 13, wherein a shape of each of the at least one first opening area is same as a shape of the corresponding display area, and a size of each of the at least one first opening area is larger than a size of the corresponding display area.

15. The mask plate as claimed in claim 13, wherein a border of each of the at least one first opening area and a border of each of the at least one second opening area both correspond to a pixel defining portion of a corresponding display panel.

16. The mask plate as claimed in claim 13, wherein each of the at least one shielding portion comprises a shielding body and a connector disposed on both sides of the shielding body, and each of the at least one shielding portion connects to the second metal frame through the connector.

17. A manufacturing method of a display panel, the display panel comprising a display area, the display area comprising an installation area configured to install a preset component and a non-installation area defined by an area of the display area excluding the installation area, wherein the manufacturing method comprises following steps:
providing the display panel, a first mask plate, and a second mask plate, wherein the first mask plate comprises a first opening area, and the second mask plate comprises a second opening area and a shielding portion;
making the first opening area of the first mask plate correspond to the display area, performing a first cathode vapor deposition in the display area, forming an initial cathode of a first sub-pixel in the non-installation area, and forming a second cathode of a second sub-pixel in the installation area; and
making the second opening area of the second mask plate correspond to the non-installation area, making the shielding portion of the second mask plate correspond to the installation area, and performing a second cathode vapor deposition on the initial cathode disposed in the display area to form a first cathode of the first sub-pixel.

18. The manufacturing method of the display panel as claimed in claim 17, wherein after the step of making the second opening area of the second mask plate correspond to the non-installation area, making the shielding portion of the second mask plate correspond to the installation area, and performing the second cathode vapor deposition on the initial cathode disposed in the display area to form the first cathode of the first sub-pixel, further comprising:
forming a first encapsulation layer on the first sub-pixel and the second sub-pixel; and
forming a first compensation layer on the first encapsulation layer, and making the first compensation layer correspond to an opening area of the second sub-pixel.

19. The manufacturing method of the display panel as claimed in claim 17, wherein after the step of making the second opening area of the second mask plate correspond to the non-installation area, making the shielding portion of the second mask plate correspond to the installation area, and performing the second cathode vapor deposition on the initial cathode disposed in the display area to form the first cathode of the first sub-pixel, further comprising:
forming a second encapsulation layer on the first sub-pixel and the second sub-pixel; and
attaching a polarizer on the second encapsulation layer, and making a second compensation layer of the polarizer correspond to an opening area of the second sub-pixel.
